(19) United States
(12) Patent Application Publication
(10) Pub. No.: US 2014/0120476 A1
(43) Pub. Date: May 1, 2014

(54) Method of forming a photoresist pattern

(71) Applicant: UNITED MICROELECTRONICS CORP., Hsin-Chu City (TW)

(72) Inventors: Tuan-Yen Yu, Tainan City (TW); Yuan-Chi Pai, Tainan City (TW); Chun-Chi Yu, Taipei City (TW)

(73) Assignee: UNITED MICROELECTRONICS CORP., Hsin-Chu City (TW)

(21) Appl. No.: 13/661,050

(22) Filed: Oct. 26, 2012

(51) Int. Cl. G03F 7/20

(52) U.S. Cl. 430/325; 430/322

(57) ABSTRACT

A method of forming a photoresist pattern, in which, a substrate is coated with a photoresist layer, an exposure process is performed on the photoresist layer to expose the photoresist layer, the photoresist layer is rinsed with a surfactant after the exposure process is performed, and the photoresist layer is post-exposure baked after the photoresist layer is rinsed with the surfactant.

### BACKGROUND OF THE INVENTION

1. Field of the Invention

The present invention relates to a method of forming a photoresist pattern.

2. Description of the Prior Art

The use of 193 nm immersion lithography is considered a solution for future device nodes in the semiconductor industry. One important issue of immersion lithography is pattern defect control. The fall-on defect becomes worse after the exposure step, in which for example, an immersion hood (IH) with an immersion media is utilized. Thus, the dirty issue is enhanced. It is difficult to remove fall-on particles, and especially sticky particles, in track side only through development with rinse material after post-exposure bake (PEB). Once the fall-on particle with a significant size remains on the developed patterned photoresist layer, for example, the particle size is greater than the line width of the patterned photoresist layer or the particle is stuck on the sidewall of the patterned photoresist layer, it results in a poor resolution for patterning the layer beneath the patterned photoresist layer.

Accordingly, a novel process of lithography is still needed for more efficiently solving the fall on defect issues.

### SUMMARY OF THE INVENTION

One objective of the present invention is to provide a method of forming a photoresist pattern, in which, contaminants in track side, from previous processes or from an immersion hood can be reduced or removed.

According to an embodiment of the present invention, a method of forming a photoresist pattern includes steps as follows. A substrate is coated with a photoresist layer. An immersion exposure process is performed on the photoresist layer to expose the photoresist layer. The photoresist layer is rinsed with a surfactant after the immersion exposure process is performed. The photoresist layer is post-exposure baked after the photoresist layer is rinsed with the surfactant.

In the method according to an embodiment of the present invention, the photoresist layer is rinsed with a surfactant between a step of performing an immersion exposure process and a step of post-exposure baking, so as to efficiently remove or minimize contaminants such as fall-on particles including water droplet residue generated from, for example, an immersion hood, or polymer from for example wafer edge exposure (WEE) or edge bead removal (EBR) process.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart illustrating a method of forming a photoresist pattern according to an embodiment of the present invention;

FIGS. 2 to 4 are schematic cross-sectional views illustrating a method of forming a photoresist pattern according to an embodiment of the present invention;

FIG. 5 is a flow chart illustrating a method of forming a photoresist pattern according to another embodiment of the present invention;

FIG. 6 is a schematically cross-sectional view illustrating a further step of developing a photoresist layer in a method of forming a photoresist pattern according to another embodiment of the present invention; and

FIGS. 7 to 9 are schematically cross-sectional views illustrating a method of forming a photoresist pattern according to further another embodiment of the present invention.

### DETAILED DESCRIPTION

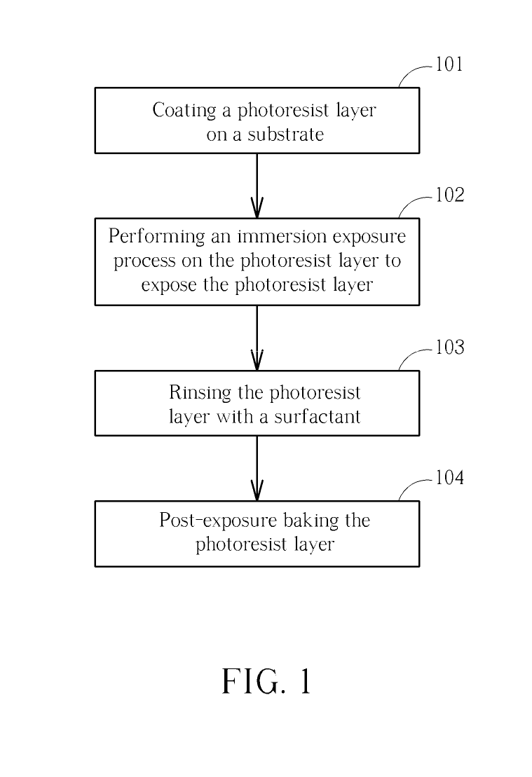

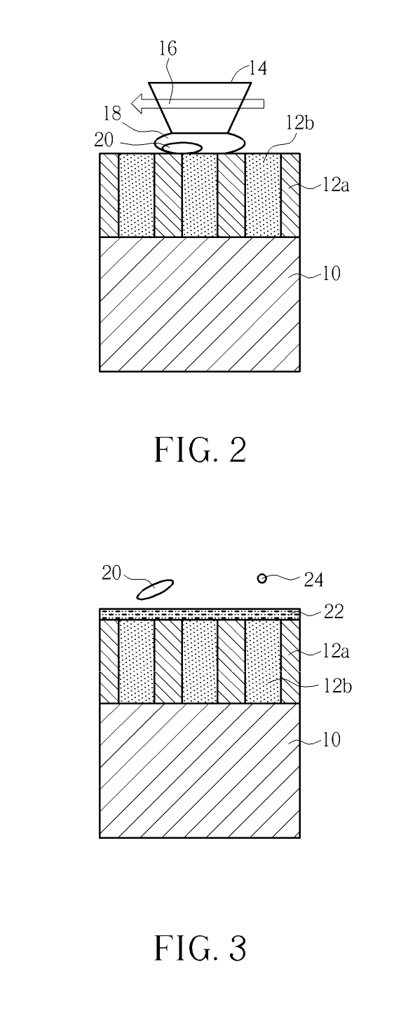

Referring to FIG. 1, a flow chart, and FIGS. 2 to 4, schematically cross-sectional views, a method of forming a photoresist pattern according to an embodiment of the present invention includes steps as follows. Referring to FIG. 1, first, Step 101 is performed to coat a photoresist layer on a substrate. The photoresist layer may be coated on the substrate using conventional means, for example, spin coating. The photoresist layer is not particularly limited and may include a positive type or a negative type of photoresist, as desired. The substrate may have a layer on top to be patterned using a desired patterned photoresist layer as a mask in an etch process.

Next, Step 102, performing an immersion exposure process on the photoresist layer to expose the photoresist layer, is performed. Specifically, an immersion exposure process may be performed through movement of an immersion lens with an immersion hood together with respect to the photoresist layer to expose the photoresist layer, and an immersion media such as water, but not limited thereto, is disposed between the photoresist layer and the immersion lens with the immersion hood together. FIG. 2 shows a substrate 10 and an unexposed portion 12a and an exposed portion 12b of photoresist layer on the substrate 10 upon exposure of the photoresist layer. An immersion hood 14 is moved in a direction shown by an arrow 16, and an immersion liquid 18 is between the immersion hood 14 and the photoresist layer. The immersion liquid 18 contacts the photoresist layer. At least a fall-on particle 20, such as a polymer particle, is on the photoresist layer, and may be immersed in the immersion liquid 18 when the immersion hood 14 passes through.

After the immersion exposure process is performed, the fall-on particle 20 may remain on the photoresist layer, and a residue of the immersion liquid may remain, too. Step 103 is performed to rinse the photoresist layer with a surfactant. As shown in FIG. 3, the surface of the photoresist layer is rinsed with a surfactant 22, such that the fall-on particle 20 and the residue of the immersion liquid 18, which may present as, for example, a liquid droplet 24, can be removed or rinsed off the photoresist layer. The liquid droplet 24 may be brought away from the photoresist layer by the surfactant 22, and the fall-on particle 20 may be rinsed away or dissolved by the surfactant to have a reduced size.

The fall-on particle 20 is not particularly limited and it may be a pollutant from the environment where the substrate is in, or it may be from a dirty immersion hood used in the immersion exposure process. The fall-on particle 20 may become stickier after it is immersed in or swelled by the immersion liquid, especially when it is a polymer particle.

The surfactant suitable for use in the present invention may include a chemical, which may a hydrocarbon or a fluorochemical, containing both hydrophobic group and hydrophilic group. Among these, the surfactant may include an ionic or non-ionic surfactant. The ionic surfactant may include anionic surfactant, cationic surfactant or amphoteric surfactant. The surfactant may be usually used in a form of solution, such as a water solution, but not limited thereto. The surfactant can be appropriately selected according to the properties of the fall-on particles and immersion liquid and photoresist layer employed in the method. Some of the properties may be for example adhesion of the fall-on particle to the photoresist layer and the contact angle of the immersion liquid with respect to the photoresist layer. AZ® FIRM™ solution, commercially available from AZ Electronic Materials Taiwan Co., Ltd., Hu Kou Township, Hsinchu County, Taiwan R.O.C., is one of preferred solutions of surfactant.

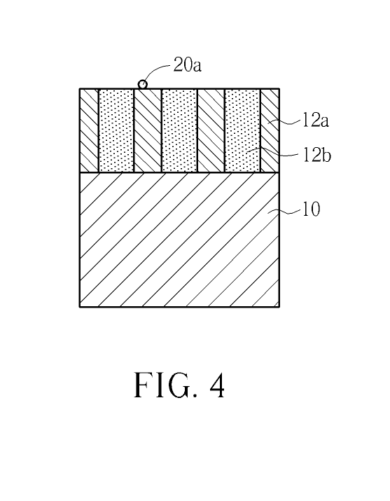

Thereafter, Step 104 is performed to post-exposure bake the photoresist layer, so as to remove residual solvent in the resist layer and to reduce standing waves. The post-exposure bake may be performed according to a conventional technology. FIG. 4 shows that a small-sized fall-on particle 20a remains on the post-exposure-baked photoresist layer. Since the fall-on particle 20a has a small size which can be less than the line width of the patterned photoresist layer, it can be easily removed during a development in the following desired procedures.

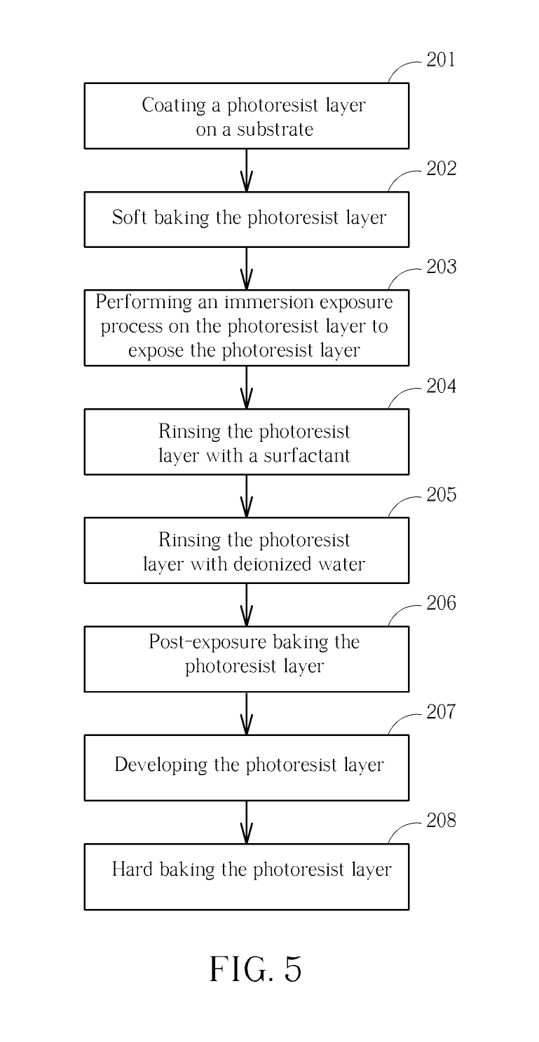

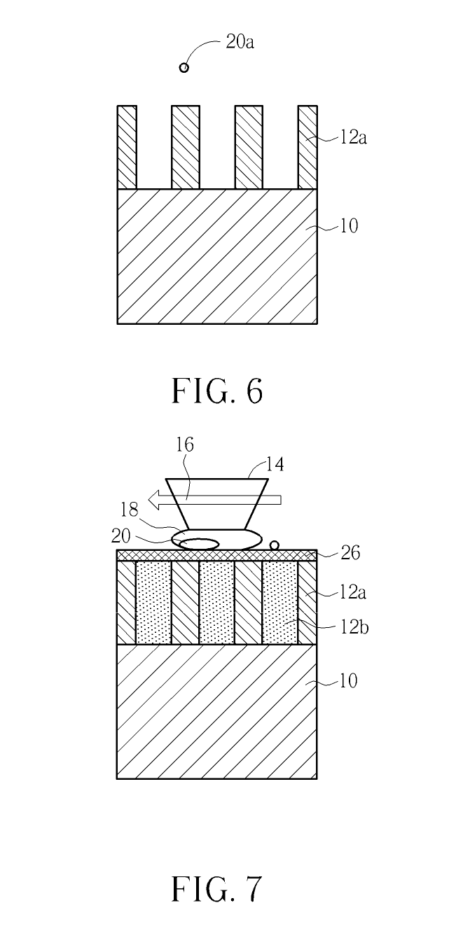

One or more additional steps as those can be performed in conventional lithography technology can be performed optionally in addition to the main steps described above. Please refer to the flow chart shown in FIG. 5. First, Step 201 is performed to coating a photoresist layer on a substrate. Next, optionally, Step 202 maybe performed to soft bake the photoresist layer, so as to remove solvent from the photoresist layer and to preliminarily harden it. Thereafter, Step 203 may be performed to perform an immersion exposure process on the photoresist layer to expose the photoresist layer, similar to Step 102 as described above. Thereafter, Step 204 is performed to rinse the photoresist layer with a surfactant, similar to Step 103 as described above. Optionally, Step 205 may be further performed to rinse the photoresist layer with deionized water. This step is also for cleaning the surface of the photoresist layer. Thereafter, Step 206 is performed to post-exposure bake the photoresist layer. Step 207 maybe further performed to develop the photoresist layer so as to remove undesired portions of the photoresist layer to form it into a pattern. FIG. 6 shows that the photoresist layer is developed and accordingly the exposed portion 12b of photoresist layer is removed. In this step, the fall-on particle 20a is small and the immersion liquid residue is rinsed off, and accordingly it can be easily removed from the photoresist layer by the development. Thereafter, optionally, Step 208 may be further performed to hard bake the photoresist layer in order to harden the patterned photoresist layer and improve adhesion of the patterned photoresist layer to the substrate surface.

The embodiment described above relates to a photolithography process without forming a top-coat on the photoresist layer, which process may be referred to as a NTC PR process (non-top coat photoresist process). In conventional NTC PR processes, fall-on defect can be aggravated by the immersion hood with the immersion media together. By using the method of forming a photoresist pattern according to the present invention, such fall-on defect can be well minimized or avoided.

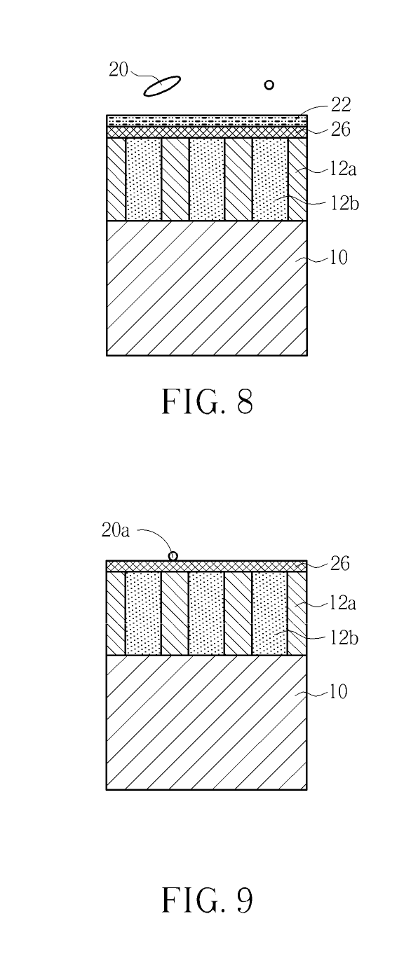

The method of forming a photoresist pattern according to another embodiment of the present invention may be also applicable to a TC PR process (top coat photo-resist process), for example, as illustrated by FIGS. 7 to 9. As shown in FIG. 7, a top-coat 26 is formed on the photoresist layer formed on a substrate 10, and the photoresist layer is exposed to become unexposed portions 12a and exposed portions 12b employing an immersion lens with an immersion hood 14 together moving in a direction shown by an arrow 16 in an immersion exposure process. An immersion liquid 18 is between the immersion hood 14 and the photoresist layer. The immersion liquid 18 contacts the top-coat 26 directly. A fall-on particle 20 is on the top-coat 26, and may be immersed in the immersion liquid 18 when the immersion hood 14 passes through. Thereafter, as shown in FIG. 8, the surface of the top-coat 26 is rinsed with a surfactant 22, such that the fall-on particle 20 and the residue of the immersion liquid 18, which may present as, for example, a liquid droplet 24, can be removed from or rinsed off the top-coat 26. FIG. 9 shows that a reduced-sized fall-on particle 20a remains on the top-coat 26, which can be easily removed along with the removal of the top-coat 26. Thereafter, the photoresist layer is post-exposure baked. Thereafter, the photoresist layer is developed and a pattern is formed, as also illustrated by FIG. 6.

The method of forming a photoresist pattern according to the present invention may be also applicable to those using an exposure process not limited to the immersion exposure process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a photoresist pattern, comprising:
coating a photoresist layer on a substrate;
performing an immersion exposure process on the photoresist layer to expose the photoresist layer;
rinsing the photoresist layer with a surfactant after performing the immersion exposure process; and
post-exposure baking the photoresist layer after rinsing the photoresist layer with the surfactant.

2. The method of claim 1, further comprising soft baking the photoresist layer before performing the immersion exposure process.

3. The method of claim 1, further comprising developing the photoresist layer after post-exposure baking the photoresist layer.

4. The method of claim 3, further comprising hard baking the photoresist layer after developing the photoresist layer.

5. The method of claim 1, further comprising rinsing the photoresist layer with deionized water after rinsing the photoresist layer with a surfactant and before post-exposure baking the photoresist layer.

6. The method of claim 1, wherein an immersion liquid is employed and the immersion liquid contacts the photoresist layer directly in the immersion exposure process.

7. The method of claim 1, wherein, a top-coat is disposed on the photoresist layer, an immersion liquid is employed in the immersion exposure process, and the immersion liquid contacts the top-coat directly in the immersion exposure process.

8. The method of claim 1, wherein, the surfactant is used in a form of solution.

9. A method of forming a photoresist pattern, comprising:
coating a photoresist layer on a substrate;
performing an exposure process on the photoresist layer to expose the photoresist layer;
rinsing the photoresist layer with a surfactant after performing the exposure process; and
post-exposure baking the photoresist layer after rinsing the photoresist layer with the surfactant.

10. The method of claim 9, further comprising soft baking the photoresist layer before performing the exposure process.

11. The method of claim 9, further comprising developing the photoresist layer after post-exposure baking the photoresist layer.

12. The method of claim 11, further comprising hard baking the photoresist layer after developing the photoresist layer.

13. The method of claim 9, further comprising rinsing the photoresist layer with deionized water after rinsing the photoresist layer with a surfactant and before post-exposure baking the photoresist layer.

14. The method of claim 9, wherein, the surfactant is used in a form of solution.
